(19) United States
(12) Patent Application Publication
(10) Pub. No.: US 2024/0006304 A1
(43) Pub. Date: Jan. 4, 2024

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Yu-Chao Lin, Hsinchu City (TW); Jung-Piao Chiu, Kaohsiung City (TW); Bo-Jiun Lin, Hsinchu County (TW); Chih-Sheng Chang, Hsinchu (TW)

(73) Assignee: Taiwan Semiconductor Manufacturing Company, Ltd., Hsinchu (TW)

(21) Appl. No.: 17/857,049

(22) Filed: Jul. 4, 2022

(51) Int. Cl. H01L 23/522; H01L 49/02; H01L 21/768; H01L 45/00

(52) U.S. Cl. CPC H01L 23/5223; H01L 28/60; H01L 23/5226; H01L 21/76832; H01L 21/76802; H01L 45/1253; H01L 45/1683

(57) ABSTRACT

A semiconductor device includes a first electrode, a first dielectric layer, a second electrode and an insulating layer. The first dielectric layer is disposed on the first electrode. The second electrode is disposed in the first dielectric layer. The insulating layer is disposed in the first dielectric layer and between the second electrode and the first electrode and between the second electrode and the first dielectric layer. The first electrode and the second electrode are electrically isolated by the insulating layer.

### BACKGROUND

Flash memory is a widely used type of nonvolatile memory. However, flash memory is expected to encounter scaling difficulties. Therefore, alternatives types of nonvolatile memory are being explored. Among these alternatives types of nonvolatile memory are resistive random access memory (RRAM) and phase change random access memory (PCRAM). RRAM and PCRAM have fast read and write times, non-destructive reads, and high scalability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1G illustrate cross-sectional views of a method of forming a semiconductor device in accordance with some embodiments of the disclosure.

FIG. 2 illustrates a cross-sectional view of a semiconductor device in accordance with some embodiments of the disclosure.

FIG. 3 illustrates a flowchart of a method of forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Source/drain region(s) may refer to a source or a drain, individually or collectively dependent upon the context.

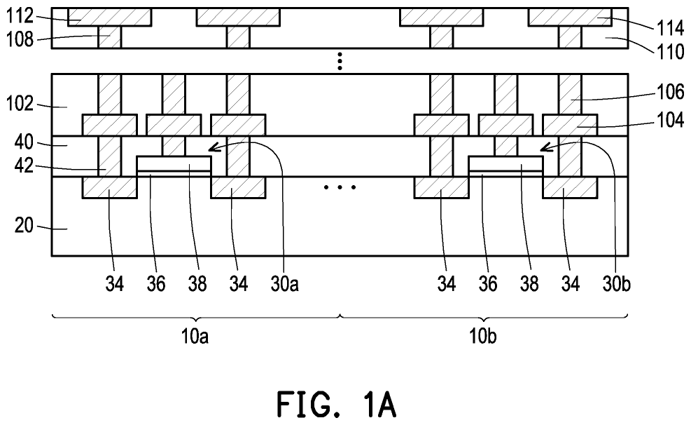

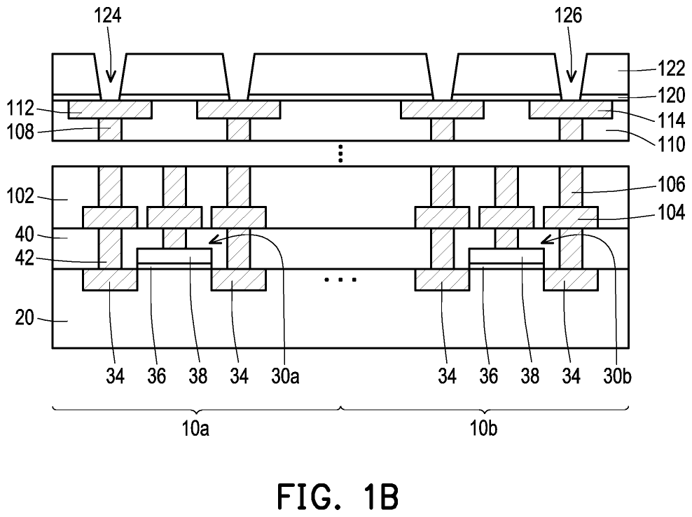

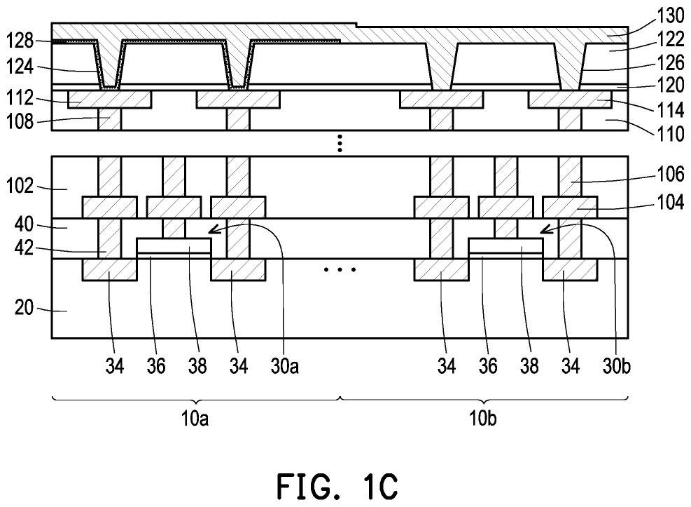

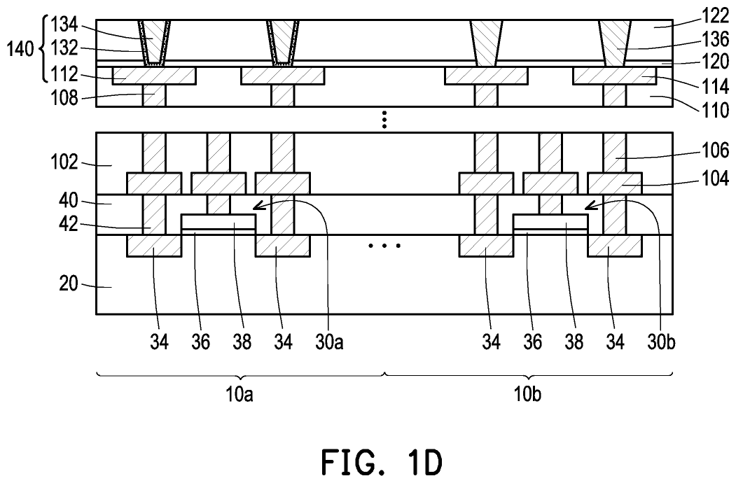

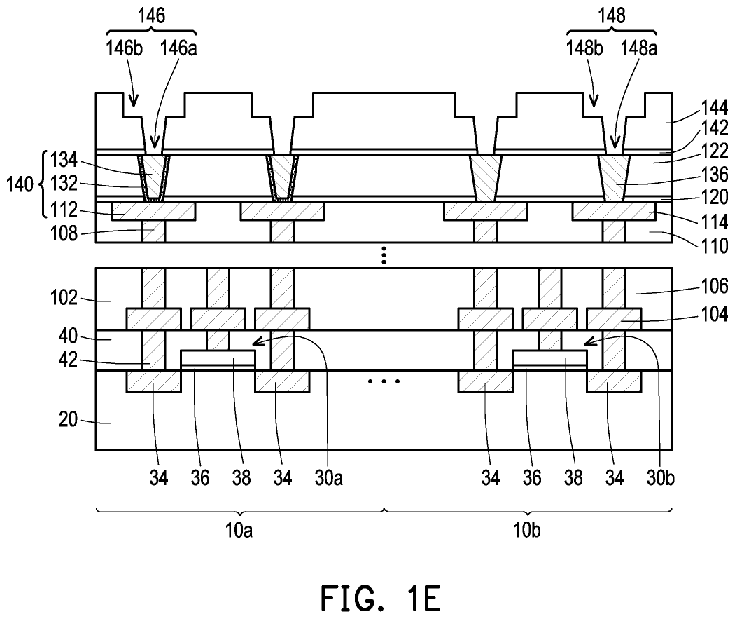

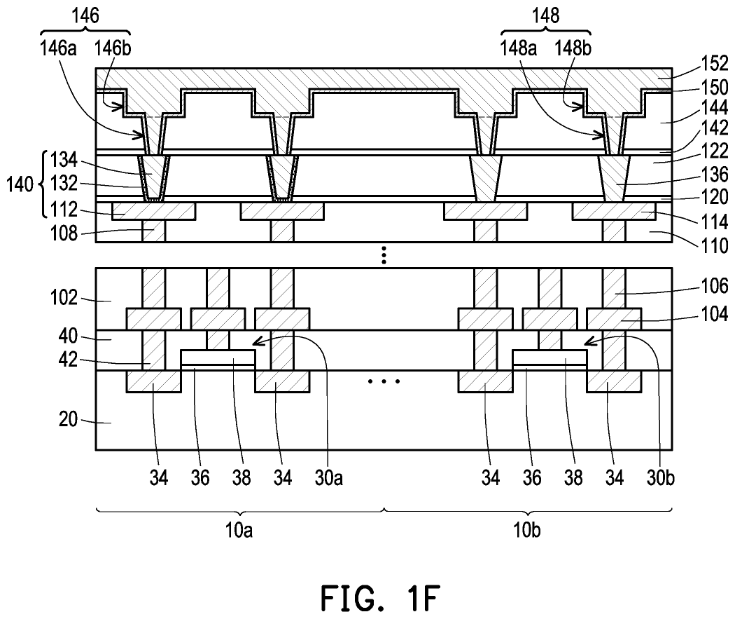

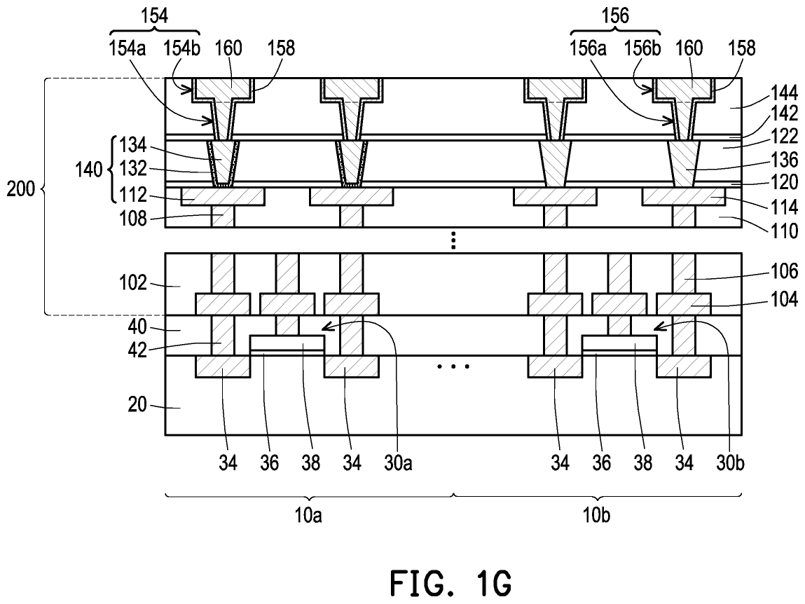

FIG. 1A to FIG. 1G illustrate cross-sectional views of a method of forming a semiconductor device in accordance with some embodiments of the disclosure.

Referring to FIG. 1A, a plurality of first electrodes 112 are formed in a first region 10a, and a plurality of conductive patterns 114 are formed in a second region 10b. In some embodiments, a plurality of first and second active devices 30a and 30b are disposed in the first region 10a and the second region 10b respectively. The first region 10a and the second region 10b are separated from each other. The first region 10a is a cell region, and the second region 10b is a logic region, for example. The first and second active devices 30a and 30b are formed on a semiconductor substrate 20, for example. The first and second active devices 30a and 30b may be metal-oxide-semiconductor filed-effect transistors (MOSFETs). The first and second active devices 30a and 30b respectively include a pair of source/drain regions 34 disposed in the semiconductor substrate 20 and laterally spaced apart, for example. A gate dielectric 36 may be disposed over the semiconductor substrate 20 between the individual source/drain regions 34, and a gate electrode 38 may be disposed over the gate dielectric 36. In some embodiments, a dielectric layer 40 is disposed over the first and second active devices 30a and 30b and the semiconductor substrate 20. The dielectric layer 40 is an interlayer dielectric (ILD) layer, for example. The dielectric layer 40 includes one or more ILD materials, for example. In some embodiments, the dielectric layer 40 includes one or more of a low-k dielectric layer (e.g., a dielectric with a dielectric constant less than about 3.9), an ultra-low-k dielectric layer, or an oxide (e.g., silicon oxide). Conductive contacts 42 are arranged within the dielectric layer 40, for example. The conductive contacts 42 may extend through the dielectric layer 40 to the gate electrode 38 and the pair of source/drain regions 34. In some embodiments, the conductive contacts 42 include copper, tungsten, or some other conductive material.

In some embodiments, at least one dielectric layer 102 and a plurality of conductive lines 104 and a plurality of conductive vias 106 disposed within the dielectric layer 102 are formed over the dielectric layer 40. The dielectric layer 102 is an inter-metal dielectric (IMD) layer, for example. The conductive lines 104 and conductive vias 106 may be configured to provide electrical connections between various devices disposed throughout the integrated circuit. In some embodiments, the dielectric layer 102 includes one or more of a low-k dielectric layer (e.g., a dielectric with a dielectric constant less than about 3.9), an ultra-low-k dielectric layer, or an oxide (e.g., silicon oxide). In some embodiments, the conductive lines 104 and conductive vias 106 are or include copper (Cu), aluminum copper (AlCu), ruthenium (Ru), titanium nitride (TiN), titanium tungsten (TiW), titanium tungsten nitride (TiWN), titanium tantalum nitride (TiTaN), tantalum nitride (TaN), tungsten (W), tungsten nitride (WN), hafnium nitride (HfN), tungsten titanium (WTi), tungsten titanium nitride (WTiN), hafnium tungsten nitride (HfWN), hafnium tungsten (HfW), titanium hafnium nitride (TiHfN), aluminum (Al), platinum (Pt), carbon (C) or the like.

In some embodiments, a dielectric layer 110 is formed over the dielectric layer 102, and the first electrodes 112 and the first conductive patterns 114 are formed in the dielectric layer 110. The dielectric layer 110 is an IMD layer, for example. The dielectric layer 110 includes one or more of a low-k dielectric layer (e.g., a dielectric with a dielectric constant less than about 3.9), an ultra-low-k dielectric layer, or an oxide (e.g., silicon oxide). The dielectric layer 110 may be formed by CVD, PVD, some other suitable deposition process(es), or a combination of the foregoing. In some embodiments, the first electrodes 112 and the conductive patterns 114 are formed by a single damascene process, a dual damascene process or other suitable process. For example, the dielectric layer 110 is patterned to form openings (e.g., trenches) corresponding to the first electrodes 112 and the conductive patterns 114 to be formed, a conductive layer is deposited to fill the openings and covers the dielectric layer 110, and a planarization process is performed on the conductive layer until the dielectric layer 110 is reached. The patterning may be performed by a photolithography/etching process and/or some other suitable patterning process(es). The depositing may be performed by CVD, PVD, electroless plating, electroplating, some other suitable deposition process(es), or a combination of the foregoing. The planarization may be performed by a CMP and/or some other suitable planarization process(es). In some embodiments, the first electrode 112 and the conductive pattern 114 are formed simultaneously by the same processes. However, the disclosure is not limited thereto. In alternative embodiments, the first electrode 112 and the conductive pattern 114 are formed separately. In some embodiments, a plurality of conductive vias 108 are further formed in the dielectric layer 110 to electrically connect the first electrodes 112 to the underlying conductive vias 106 in the first region 10a, and similarly, a plurality of conductive vias 108 are further formed in the dielectric layer 110 to electrically connect the conductive patterns 114 to the underlying conductive vias 106 in the second region 10b. In alternative embodiments, the first electrode 112 and the conductive via 108 therebeneath are integrally formed by a dual damascene process, and similarly, the conductive pattern 114 and the conductive via 108 therebeneath are integrally formed by a dual damascene process. However, the disclosure is not limited thereto. In alternative embodiments, the first electrodes 112 and the conductive patterns 114 have other electrical connections to the underlying active devices 30a, 30b respectively.

In some embodiments, the first electrode 112 and the conductive pattern 114 are or include copper (Cu), aluminum copper (AlCu), ruthenium (Ru), titanium nitride (TiN), titanium tungsten (TiW), titanium tungsten nitride (TiWN), titanium tantalum nitride (TiTaN), tantalum nitride (TaN), tungsten (W), tungsten nitride (WN), hafnium nitride (HfN), tungsten titanium (WTi), tungsten titanium nitride (WTiN), hafnium tungsten nitride (HfWN), hafnium tungsten (HfW), titanium hafnium nitride (TiHfN), aluminum (Al), platinum (Pt), carbon (C) or the like.

In some embodiments, first surfaces (e.g., top surfaces) of the first electrodes 112 and the conductive patterns 114 are substantially coplanar with a surface (e.g., top surface) of the dielectric layer 110. Second surfaces (e.g., bottom surfaces) opposite to the first surfaces of the first electrodes 112 and the conductive patterns 114 are substantially coplanar with each other. In such embodiments, the openings for forming the first electrodes 112 and the conductive patterns 114 have the same depth. However, the disclosure is not limited thereto. In alternative embodiments, the second surfaces (e.g., bottom surfaces) of the first electrodes 112 and the conductive patterns 114 are not coplanar. In some embodiments, the conductive patterns 114 are parts of the interconnect structure such as conductive lines of a first metallization layer. For example, the first electrodes 112 has surfaces substantially coplanar with a metallization layer of the interconnect structure including the conductive patterns 114.

Referring to FIG. 1B, a dielectric layer 122 is formed on the dielectric layer 110. Then, a plurality of via holes 124, 126 are formed in the dielectric layer 122. In some embodiments, an etch stop layer 120 is formed over the dielectric layer 110, and the dielectric layer 122 is formed on the etch stop layer 120. Then, the via holes 124 are formed in the etch stop layer 120 and the dielectric layer 122 in the first region 10a, to respectively expose the first electrodes 112, for example. The via holes 126 are formed in the etch stop layer 120 and the dielectric layer 122 in the second region 10b, to respectively expose the conductive patterns 114, for example. The dielectric layer 122 is an IMD layer, for example. The dielectric layer 122 includes one or more of a low-k dielectric layer (e.g., a dielectric with a dielectric constant less than about 3.9), an ultra-low-k dielectric layer, or an oxide (e.g., silicon oxide). The dielectric layer 122 may be formed by CVD, PVD, some other suitable deposition process(es), or a combination of the foregoing. The etch stop layer 120 is disposed between the dielectric layer 110 and the dielectric layer 122 and covers the first electrode 112 and the conductive pattern 114, for example. The etch stop layer 120 may include SiC, aluminum oxide (AlOₓ), SiN or the like. In some embodiments, a thickness of the dielectric layer 122 is in a range of about 80 nm to about 120 nm. In some embodiments, a thickness of the etch stop layer 120 is in a range of about 5 nm to about 20 nm.

The via holes 124, 126 may be formed using any suitable process, such as a single damascene process, a dual damascene process, a combination thereof or the like. For example, a photoresist is formed on the dielectric layer 122. The photoresist may be formed by spin coating or the like and may be exposed to light for patterning. The pattern of the photoresist corresponds to openings for the via holes 124, 126. Then, the dielectric layer 122 and the etch stop layer 120 are patterned to form the via holes 124, 126 using the patterned photoresist as a mask with the patterning process, for example. The exposed portions of the dielectric layer 122 and the etch stop layer 120 may be removed by using an acceptable etching process, such as by wet and/or dry etching. The photoresist may be then removed by an acceptable ashing or stripping process, such as using an oxygen plasma or the like. In some embodiments, a critical dimension (e.g., bottom width) of the via holes 124, 126 is in a range of about 20 nm to about 40 nm.

Referring to FIG. 1C, an insulating material 128 is formed on exposed surfaces of the via holes 124 and the dielectric layer 122 in the first region 10a while the via holes 126 in the second region 10b are masking. In some embodiments, the insulating material 128 is conformally formed over the exposed surfaces of the first region 10a, and the second region 10b is entirely covered by a mask. For example, the insulating material 128 is conformally formed on sidewalls and the bottom surfaces of the via holes 124 and a first surface (e.g., top surface) of the dielectric layer 122. In some embodiments, the insulating material 128 is in direct contact with the sidewalls and the bottom surfaces of the via holes 124 and the first surface (e.g., top surface) of the dielectric layer 122. The insulating material 128 is formed on the sidewalls and the bottom surfaces of the via holes 124 without filling up the via holes 124. The insulating material 128 may be formed by CVD, PVD, some other suitable deposition process(es), or a combination of the foregoing. In some embodiments, a thickness of the insulating material 128 is in a range of about 20 nm to about 50 nm.

The insulating material 128 may be a data storage material (also referred to as a memory material layer) for RRAM, PCRAM, FeRAM, ARAM (audio DRAM), CBRAM (conductive-bridging RAM) or other type of memory or other suitable insulating material. In some embodiments, the data storage material for RRAM has a resistance variable material which is configured to store data states by undergoing reversible changes between a high resistance state associated with a first data state (e.g., a “0”) and a low resistance state associated with a second data state (e.g., a “1”). The resistance variable material includes transition metal oxide materials or alloys including two or more metals, such as transition metals, alkaline earth metals, and/or rare earth metals. In some embodiments, the data storage material for PCRAM is or include a phase change material such as a chalcogenide material. The chalcogenide material includes an indium(In)-antimony(Sb)-tellurium(Te) (IST) material or a germanium(Ge)-antimony(Sb)-tellurium(Te) (GST) material, for example. The ISG material may include In₂Sb₂Te₅, In₁Sb₂Te₄, In₁Sb₄Te₇ or the like. The GST material may include Ge₈Sb₅Te₈, Ge₂Sb₂Te₅, Ge₁Sb₂Te₄, Ge₁Sb₄Te₇, Ge₄Sb₄Te₇, Ge₄SbTe₂, Ge₆SbTe₂ or the like. The hyphenated chemical composition notation, as used herein, indicates the elements included in a particular mixture or compound, and is intended to represent all stoichiometries involving the indicated elements. Other phase change materials may include Ge—Te, In—Se, Sb—Te, Ga—Sb, In—Sb, As—Te, Al—Te, Ge—Sb—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt. In some embodiments, the data storage material for FeRAM is or include a ferroelectric material such as hafnium zirconium oxide (HfZrO), hafnium aluminum oxide (HfAlO), hafnium lanthanum oxide (HfLaO), hafnium cerium oxide (HfCeO), hafnium oxide (HfO₂), hafnium gadolinium oxide (HfGdO), hafnium silicon oxide (HfSiO) or a combination thereof.

Then, a conductive material 130 is formed to fill up the via holes 124 and the via holes 126. In some embodiments, after formation of the conductive material 130, the mask over the second region 10b is removed. The conductive material 130 is formed on the insulating material 128 in the first region 10a and on the dielectric layer 122 in the second region 10b, for example. The conductive material 130 may be in direct contact with the insulating material 128 in the first region 10a and the dielectric layer 122 in the second region 10b. The conductive material 130 simultaneously fills up the via holes 124 and the via holes 126. The conductive material 130 may be formed by CVD, PVD, electroless plating, electroplating, some other suitable deposition process(es), or a combination of the foregoing.

In some embodiments, the conductive material 130 is or includes titanium nitride (TiN), tungsten (W), tungsten nitride (WN), ruthenium (Ru), titanium tungsten (TiW), titanium tungsten nitride (TiWN), titanium tantalum nitride (TiTaN), tantalum nitride (TaN), hafnium nitride (HfN), tungsten titanium (WTi), tungsten titanium nitride (WTiN), hafnium tungsten nitride (HfWN), hafnium tungsten (HfW), titanium hafnium nitride (TiHfN), aluminum (Al), platinum (Pt), carbon (C) or the like. The conductive material 130 may include the same material as the first electrodes 112 and the conductive patterns 114. In alternative embodiments, the conductive material 130 have different materials from the first electrodes 112 and the conductive patterns 114.

Referring to FIG. 1D, after forming the conductive material 130, the insulating material 128 and the conductive material 130 outside the via holes 124, 126 are removed, so as to form an insulating layer 132 and a second electrode 134 in the via hole 124 and a conductive pattern 136 in the via hole 126. In some embodiments, the removal process includes a planarization process such as a CMP and/or some other suitable planarization process(es). The planarization process is performed on the conductive material 130 until the dielectric layer 122 is reached.

In some embodiments, in the first region 10a, the first electrode 112 and the insulating layer 132 and the second electrode 134 in the via hole 124 form an MIM (metal-insulator-metal) structure 140 such as a capacitor or a memory cell. For example, when the insulating layer 132 includes a data storage material, the MIM structure 140 is a memory cell such as a RRAM cell, a PCRAM cell, a FERAM cell, an ARAM cell, a CBRAM cell or any other suitable memory cell, and includes the first electrode 112, the second electrode 134 and the data storage layer of the insulating layer 132 therebetween. Otherwise, the MIM structure 140 may be used as a capacitor. In an embodiment in which the insulating layer 132 has a resistance variable material, the MIM structure 140 is a RRAM cell. For example, to achieve a low resistance state within the insulating layer 132, a first set of bias conditions may be applied to the first electrode 112 and the second electrode 134. The first set of bias conditions drive oxygen from the insulating layer 132 to the first electrode 112, thereby forming conductive filaments of oxygen vacancies across the insulating layer 132. Alternatively, to achieve a high resistance state within the insulating layer 132, a second set of bias conditions may be applied to the first electrode 112 and the second electrode 134. The second set of bias conditions break the conductive filaments by driving oxygen from the second electrode 134 to the insulating layer 132. In an embodiment in which the insulating layer 132 has a phase change material, the MIM structure 140 is a PCRAM cell. In an embodiment in which the insulating layer 132 has a ferroelectric material, the MIM structure 140 is a FeRAM cell.

In some embodiments, the insulating layer 132 and the second electrode 134 are both formed in the via hole 124. The insulating layer 132 may be disposed on the sidewall and the bottom surface of the via hole 124 of the dielectric layer 122, and the second electrode 134 may fill up the via hole 124. The insulating layer 132 is disposed between the first electrode 112 and the second electrode 134 and between the second electrode 134 and the dielectric layer 122, for example. The insulating layer 132 may be in direct contact with the dielectric layer 122, the first electrode 112 and the second electrode 134. The second electrode 134 is separated from and electrically isolated from the first electrode 112 by the insulating layer 132 therebetween. The insulating layer 132 may be disposed on a sidewall and a surface (e.g., bottom surface) of the second electrode 134 facing the first electrode 112. For example, the insulating layer 132 surrounds the second electrode 134. In some embodiments, a first surface (e.g., top surface) of the insulating layer 132 is substantially coplanar with first surfaces (e.g., top surfaces) of the second electrode 134, the dielectric layer 122 and the conductive pattern 136. A second surface (e.g., bottom surface) opposite to the first surface of the insulating layer 132 is substantially coplanar with a surface (e.g., bottom surface) of the etch stop layer 120, a second surface (e.g., bottom surface) opposite to the first surface of the conductive pattern 136 and the first surface (e.g., top surface) of the first electrode 112.

In some embodiments, in the second region 10b, the conductive patterns 136 are formed in the via holes 126 respectively. The conductive pattern 136 is electrically connected to the conductive pattern 114 therebelow. The conductive pattern 136 may be in direct contact with the conductive pattern 114. In some embodiments, the conductive patterns 136 are parts of the interconnect structure such as conductive vias of a second metallization layer on the first metallization layer including the conductive patterns 114. For example, the first metallization layer and the second metallization layer are two metallization layers sequentially and continuously disposed in the interconnect structure. In some embodiments, the conductive patterns 136 are conductive vias while the conductive patterns 114 are conductive lines. In alternative embodiments, a barrier layer and/or a liner layer is further disposed between the conductive pattern 136 and the conductive pattern 114 and between the conductive pattern 136 and the dielectric layer 122. In some embodiments, the first surface (e.g., top surface) of the conductive pattern 136 is substantially coplanar with the first surfaces (e.g., top surfaces) of the dielectric layer 122 and the insulating layer 132 and the second electrode 134 of the MIM structure 140. In other words, after formation of the MIM structure 140 such as memory cells in the first region 10a, there is substantially no step height between the first region 10a and the second region 10b, for example.

Referring to FIG. 1E, after formation of the MIM structures 140, a dielectric layer 144 is formed over the first region 10a and the second region 10b. In some embodiments, an etch stop layer 142 is formed over the dielectric layer 122, the MIM structures 140, and the conductive patterns 136, and the dielectric layer 144 is formed on the etch stop layer 142. The dielectric layer 144 is an IMD layer, for example. The dielectric layer 144 includes one or more of a low-k dielectric layer (e.g., a dielectric with a dielectric constant less than about 3.9), an ultra-low-k dielectric layer, or an oxide (e.g., silicon oxide). The dielectric layer 144 may be formed by CVD, PVD, some other suitable deposition process(es), or a combination of the foregoing. The etch stop layer 142 is disposed between the dielectric layer 122 and the dielectric layer 144 and covers the second electrode 134 and the conductive pattern 136, for example. The etch stop layer 142 may include SiC, aluminum oxide (AlOₓ), SiN or the like. In some embodiments, a thickness of the dielectric layer 144 is in a range about 20 nm to about 300 nm. In some embodiments, a thickness of the etch stop layer 142 is in a range of about 5 nm to about 20 nm.

Then, a plurality of openings 146, 148 are formed in the etch stop layer 142 and the dielectric layer 144, for example. The openings 146, 148 expose the MIM structure 140 and the conductive pattern 136 respectively. The opening 146 in the first region 10a at least exposes the second electrode 134 of the MIM structure 140. The openings 146, 148 may be formed using any suitable process, such as a single damascene process, a dual damascene process, a combination thereof or the like. In some embodiments, the openings 146, 148 includes a via portion 146a, 148a and a trench portion 146b, 148b on the via portion 146a, and is formed by a dual damascene process. For example, a photoresist is formed on the dielectric layer 144. The photoresist may be formed by spin coating or the like and may be exposed to light for patterning. The pattern of the photoresist corresponds to openings for the openings 146, 148. Then, the dielectric layer 144 and the etch stop layer 142 are patterned to form the openings 146, 148 using the patterned photoresist as a mask with the patterning process, for example. The exposed portions of the dielectric layer 144 and the etch stop layer 142 may be removed by using an acceptable etching process, such as by wet and/or dry etching. The photoresist may be then removed by an acceptable ashing or stripping process, such as using an oxygen plasma or the like.

Referring to FIG. 1F, a conductive material 152 is formed over the dielectric layer 144 to fill up the openings 146, 148. In some embodiments, the conductive material 152 is formed on a barrier material 150. For example, before forming the conductive material 152, a barrier material 150 is conformally formed over exposed surfaces of the first region 10a and the second region 10b. The barrier material 150 may be conformally formed on sidewalls and the bottom surfaces of the openings 146, 148 and a first surface (e.g., top surface) of the dielectric layer 144. Then, portions of the barrier material 150 at the bottom surfaces of the openings 146, 148 may be removed to expose the MIM structure 140 and the conductive pattern 136 respectively. The barrier material 150 may by using an acceptable etching process, such as by wet and/or dry etching. In some embodiments, the barrier material 150 is in direct contact with the sidewalls of the openings 146, 148 and the first surface (e.g., top surface) of the dielectric layer 144. The barrier material 150 is formed on the sidewalls of the openings 146, 148 without filling up the openings 146, 148. In some embodiments, the barrier material 150 is or includes titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), a combination thereof or the like. The barrier material 150 may be formed by CVD, PVD, some other suitable deposition process(es), or a combination of the foregoing. In some embodiments, a thickness of the barrier material 150 is in a range of about 20 nm to about 50 nm. Then, the conductive material 152 is formed over the barrier material 150 to fill up the openings 146, 148 in the first region 10a and the second region 10b. The conductive material 152 may be in direct contact with the barrier material 150 and the MIM structure 140 and the conductive pattern 136 exposed by the barrier material 150. The conductive material 152 simultaneously fills up the openings 146, 148 in the first region 10a and the second region 10b. The conductive material 152 may be formed by CVD, PVD, electroless plating, electroplating, some other suitable deposition process(es), or a combination of the foregoing.

In some embodiments, the conductive material 152 is or includes titanium nitride (TiN), tungsten (W), tungsten nitride (WN), ruthenium (Ru), titanium tungsten (TiW), titanium tungsten nitride (TiWN), titanium tantalum nitride (TiTaN), tantalum nitride (TaN), hafnium nitride (HfN), tungsten titanium (WTi), tungsten titanium nitride (WTiN), hafnium tungsten nitride (HfWN), hafnium tungsten (HfW), titanium hafnium nitride (TiHfN), aluminum (Al), platinum (Pt), carbon (C) or the like. The conductive material 152 may include the same material as the first electrodes 112 and the conductive patterns 114. In alternative embodiments, the conductive material 152 have different materials from the first electrodes 112 and the conductive patterns 114.

Referring to FIG. 1G, the barrier material 150 and the conductive material 152 outside the openings 146, 148 are removed, so as to form a plurality of conductive patterns 154, 156 in the openings 146, 148 respectively. In some embodiments, the removal process includes a planarization process such as a CMP and/or some other suitable planarization process(es). The planarization process is performed on the conductive material 152 until the dielectric layer 144 is reached. In some embodiments, as mentioned before, after formation of the MIM structure 140 such as memory cells in the first region 10a (e.g., cell region), a step height between the first region 10a (e.g., cell region) and the second region 10b (e.g., logic region) is prevented or eliminated. Accordingly, the conductive material 152 formed over the dielectric layer 144 may have a substantially flat top surface, and the planarization process may be thus performed on the substantially flat top surface of the conductive material 152. As a result, the planarization process may remove the excess material entirely. For example, the material undesirably remained between the first region 10a (e.g., cell region) and the second region 10b (e.g., logic region) due to the step height is prevented.

In some embodiments, the conductive pattern 154 is disposed in the first region 10a and is electrically connected to the second electrode 134 of the MIM structure 140, and the conductive pattern 156 is disposed in the second region 10b and is electrically connected to the conductive pattern 136 of the interconnect structure. In some embodiments, the conductive pattern 154 and the conductive pattern 156 each include a conductive layer 160 and a barrier layer 158 on a sidewall of the conductive layer 160. For example, the barrier layer 158 surrounds the sidewall of the conductive layer 160. Accordingly, the conductive layer 160 of the conductive pattern 154 is in direct contact with the second electrode 134 of the MIM structure 140, and the conductive layer 160 of the conductive pattern 156 is in direct contact with the conductive pattern 136 of the interconnect structure, for example. However, the disclosure is not limited thereto. In alternative embodiments, the barrier layer 158 is omitted, or the barrier layer 158 is further disposed between the conductive layer 160 and the MIM structure 140 or between the conductive layer 160 and the conductive pattern 136. In some embodiments, first surfaces (e.g., top surfaces) of the conductive pattern 154 in the first region 10a and the conductive pattern 156 in the second region 10b are substantially coplanar with each other and coplanar with a surface (e.g., top surface) of the dielectric layer 144. For example, first surfaces (e.g., top surfaces) of the conductive layers 160 and the barrier layers 158 of the conductive patterns 154, 156 are substantially coplanar with the surface (e.g., top surface) of the dielectric layer 144. In some embodiments, second surfaces (e.g., bottom surfaces) opposite to the first surfaces of the conductive patterns 154, 156 are substantially coplanar with each other. In some embodiments, second surfaces (e.g., bottom surfaces) of the conductive layers 160 and the barrier layers 158 of the conductive patterns 154, 156 are substantially coplanar with a surface (e.g., bottom surface) of the etch stop layer 142.

The conductive pattern 154 may include a conductive via 154a on the second electrode 134 and a conductive line 154b on the conductive via 154a. In some embodiments, the conductive via 154a is in direct contact with the second electrode 134, and the conductive line 154b is in direct contact with the conductive via 154a between the second electrode 134 and the conductive line 154b. Similarly, the conductive pattern 156 may include a conductive via 156a on the conductive pattern 136 and a conductive line 156b on the conductive via 156a. In some embodiments, the conductive via 156a is in direct contact with the conductive pattern 136, and the conductive line 156b is in direct contact with the conductive via 154a between the conductive pattern 136 and the conductive line 154b. However, the disclosure is not limited thereto. In alternative embodiments, the conductive pattern 154 and the conductive pattern 156 are conductive lines in direct contact with the second electrode 134 and the conductive pattern 136 respectively. In such embodiments, a width (e.g., a bottom width) of the conductive pattern 154 and the conductive pattern 156 is not smaller than a width (e.g., a top width) of the second electrode 134 and the conductive pattern 136. In alternative embodiments, the conductive pattern 154 and the conductive pattern 156 are conductive vias in direct contact with the second electrode 134 and the conductive pattern 136 respectively. In such embodiments, a width (e.g., a bottom width) of the conductive pattern 154 and the conductive pattern 156 is not larger than a width (e.g., a top width) of the second electrode 134 and the conductive pattern 136.

In some embodiments, the conductive patterns 154 and the conductive patterns 156 are parts of the interconnect structure such as conductive vias and conductive lines of a third metallization layer on the second metallization layer including the conductive patterns 136 and the first metallization layer including the conductive patterns 114. For example, the first metallization layer, the second metallization layer and the third metallization layer are sequentially and continuously disposed in the interconnect structure. In some embodiments, the conductive patterns 114, 136, 154 and 156 in the dielectric layers 110, 122 and 144 along with the conductive lines 104 and the conductive vias 106 in the dielectric layer 102 form the interconnect structure 200, and the MIM structures 140 are embedded in the interconnect structure 200. However, the disclosure is not limited thereto. The MIM structures 140 may be disposed at any other suitable location. In addition, the interconnect structure 200 and the active devices 30a, 30b therebelow may have any other suitable configuration.

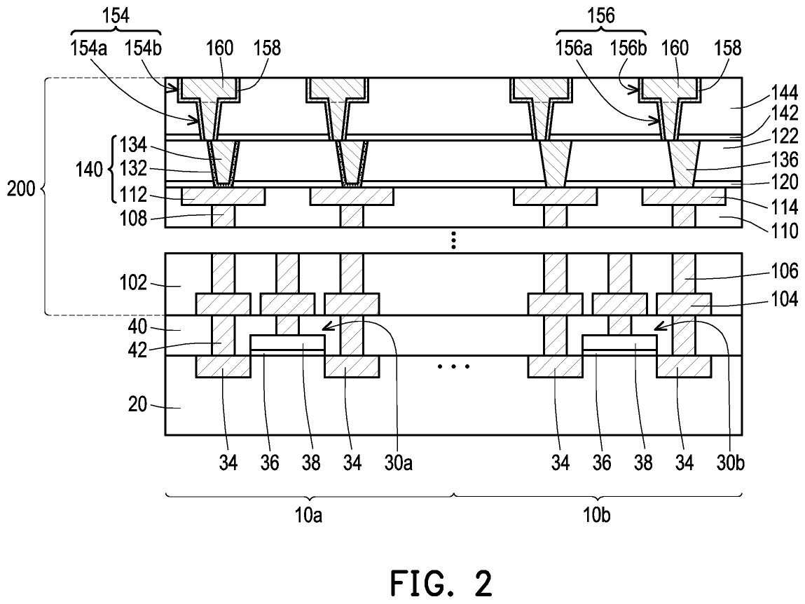

In some embodiments, as shown in FIG. 1G, a bottom of the conductive pattern 154 is entirely overlapped with the second electrode 134 of the MIM structure 140 therebelow, and similarly, a bottom of the conductive pattern 156 is entirely overlapped with the conductive pattern 136 therebelow. For example, a bottom area of the conductive pattern 154 is smaller than the second electrode 134, and similarly, a bottom area of the conductive pattern 156 is smaller than the conductive pattern 136 therebelow. In some embodiments, a middle line of the conductive pattern 154 is substantially aligned with a middle line of the second electrode 134, and similarly, a middle line of the conductive pattern 156 of the conductive pattern 156 is substantially aligned with a middle line of the conductive pattern 136. However, the disclosure is not limited thereto. As shown in FIG. 2, the conductive pattern 154 may be partially overlapped with the second electrode 134 of the MIM structure 140 as long as the conductive layer 160 is in direct contact with the second electrode 134. For example, the conductive layer 160 is partially overlapped with the second electrode 134 of the MIM structure 140. Similarly, the conductive pattern 156 may be partially overlapped with the conductive pattern 136 as long as the conductive layer 160 is in direct contact with the conductive pattern 136. For example, the conductive layer 160 is partially overlapped with the conductive pattern 136. In such embodiments, a middle line of at least one conductive pattern 154 may be offset with respect to a middle line of the second electrode 134 by a horizontal distance, and a middle line of at least one conductive pattern 156 may be offset with respect to a middle line of the conductive pattern 136 by a horizontal distance. Thus, the via-photo overlay window may be wider since there is no barrier layer on the sidewall of the via hole 124. In FIG. 2, the conductive patterns 154 or 156 are illustrated as being offset with respect to the second electrodes 134 or the conductive patterns 136 therebelow along a first direction. However, the disclosure is not limited thereto. In alternative embodiments, the conductive patterns 154 or 156 are illustrated as being offset with respect to the second electrodes 134 or the conductive patterns 136 therebelow along a second direction opposite to the first direction. In addition, in some embodiments, some conductive pattern 154 or 156 are offset with respect to the second electrodes 134 or the conductive patterns 136 therebelow, and some conductive patterns 154 or 156 are not offset with respect to the second electrodes 134 or the conductive patterns 136 therebelow.

In some embodiments (not shown), the MIM structures 140 are disposed between and electrically connected to a plurality of first lines (e.g., word lines) and a plurality of second lines (e.g., bit lines). The first electrodes 112 of the MIM structures 140 may be electrically connected to the first lines, and the second electrodes 134 of the MIM structures 140 may be electrically connected to the second lines. In some embodiments, the MIM structures 140 are arranged in an array having a plurality of rows and a plurality of columns. The first conductive lines may each extend laterally in a first direction, and the first conductive lines are arranged in parallel with one another. The second conductive lines may each extend laterally in a second direction substantially perpendicular to the first direction, and the second conductive lines are arranged in parallel with one another.

In some embodiments (not shown), there are N (N is a whole number 1 or greater) first conductive lines beneath the MIM structures 140 and there are N first active devices 30a. Each of the first conductive lines are electrically coupled to an individual first active device 30a (e.g., to a source/drain region 34 of each active device 30a) through the conductive lines 104 and the conductive vias 106, for example. In some embodiments (not shown), there are M (M is a whole number 1 or greater) second conductive lines over the MIM structures 140 and there are M second active device 30b. Each of the second conductive lines are electrically coupled to an individual second active device 30b (e.g., to a source/drain region 34 of each second active device 30b) through the conductive lines 104 and the conductive vias 106, for example.

In some embodiments, the MIM structure 140 such as a memory cell is formed in the via hole. Thus, the critical dimension of the MIM structure 140 may be reduced. For example, the contact critical dimension (e.g., the critical dimension of the conductive via (e.g., conductive via 106) contacting the first electrode 112) of the MIM structure 140 is reduced, and thus the device operation of the MIM structure 140 such as a PCRAM is improved (e.g., faster). Furthermore, the MIM structure 140 is embedded and integrated in the interconnect structure. In some embodiments, the MIM structure 140 is formed simultaneously with the conductive line (e.g., conductive pattern 114) and the conductive via (e.g., conductive pattern 136) of the interconnect structure, and thus the surfaces of the MIM structure 140 in the first region 10a (e.g., cell region) and the interconnect structure (e.g., conductive pattern 136) in the second region 10b (e.g., logic region) are substantially coplanar and collectively provides a flat surface for the subsequential interconnect structure. Accordingly, during the following planarization process, the residues (e.g., metal residues) undesirably remained between the cell region and the logic region due to the step height may be prevented. In addition, the MIM structure is not formed by patterning stacking materials, and thus the plasma damage issue caused by dry etching process may be avoided. Thus, the formed semiconductor device may have an improved performance.

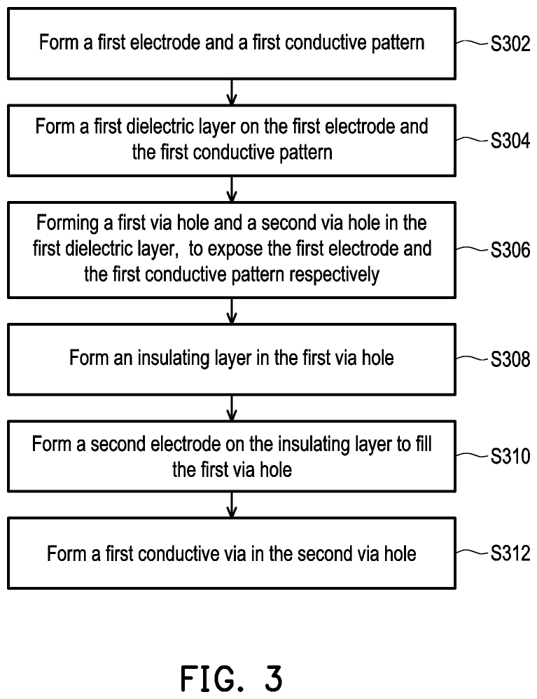

FIG. 3 illustrates a flowchart of a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 5302, a first electrode and a first conductive pattern are formed. FIG. 1A and FIG. 2 illustrate views corresponding to some embodiments of act 5302.

At act 5304, a first dielectric layer is formed on the first electrode and the first conductive pattern. FIG. 1B and FIG. 2 illustrate views corresponding to some embodiments of act 5304.

At act 5306, a first via hole and a second via hole are formed in the first dielectric layer, to expose the first electrode and the first conductive pattern respectively. FIG. 1B and FIG. 2 illustrate views corresponding to some embodiments of act 5306.

At act 5308, an insulating layer is formed in the first via hole. FIG. 1C, FIG. 1D and FIG. 2 illustrate views corresponding to some embodiments of act 5308.

At act 5310, a second electrode is formed on the insulating layer to fill the first via hole. FIG. 1C, FIG. 1D and FIG. 2 illustrate views corresponding to some embodiments of act 5310.

At act 5312, a first conductive via is formed in the second via hole. FIG. 1C, FIG. 1D and FIG. 2 illustrate views corresponding to some embodiments of act 5312.

According to some embodiments, a semiconductor device includes a first electrode, a first dielectric layer, a second electrode and an insulating layer. The first dielectric layer is disposed on the first electrode. The second electrode is disposed in the first dielectric layer. The insulating layer is disposed in the first dielectric layer and between the second electrode and the first electrode and between the second electrode and the first dielectric layer. The first electrode and the second electrode are electrically isolated by the insulating layer.

According to some embodiments, a semiconductor device includes a memory cell, a first conductive line and a first conductive via. The memory cell includes a first electrode, a second electrode and a data storage layer. The first electrode is disposed in a first dielectric layer. The second electrode is disposed in a second dielectric layer on the first dielectric layer. The data storage layer is disposed in the second dielectric layer and surrounds the second electrode. The first conductive line is disposed in the first dielectric layer. The first conductive via is disposed on the first conductive line in the second dielectric layer. Surfaces of the second electrode and the data storage layer are substantially coplanar with a surface of the first conductive via.

According to some embodiments, a method of forming a memory device includes following steps. A first electrode and a first conductive pattern are formed. A first dielectric layer is formed on the first electrode and the first conductive pattern. A first via hole and a second via hole are formed in the first dielectric layer, to expose the first electrode and the first conductive pattern respectively. An insulating layer is formed in the first via hole. A second electrode is formed on the insulating layer to fill the first via hole. A first conductive via is formed in the second via hole.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first electrode;
a first dielectric layer on the first electrode;
a second electrode in the first dielectric layer; and
an insulating layer in the first dielectric layer and between the second electrode and the first electrode and between the second electrode and the first dielectric layer, wherein the first electrode and the second electrode are electrically isolated by the insulating layer.

2. The semiconductor device of claim 1, wherein the insulating layer comprises a resistance variable material, a phase change material or a ferroelectric material.

3. The semiconductor device of claim 1, wherein the first electrode, the second electrode and the insulating layer form a capacitor, a RRAM, a PCRAM or a FERAM.

4. The semiconductor device of claim 1, wherein the insulating layer surrounds a sidewall of the second electrode.

5. The semiconductor device of claim 1, further comprising a first etch stop layer between the first electrode and the first dielectric layer and surrounds a portion of the insulating layer between the first electrode and the second electrode.

6. The semiconductor device of claim 1, wherein a surface of the second electrode is substantially coplanar with surfaces of the insulating layer and the first dielectric layer.

7. The semiconductor device of claim 1, wherein the insulating layer is in direct contact with the first electrode and the second electrode.

8. The semiconductor device of claim 1, wherein the insulating layer is in direct contact with the first dielectric layer.

9. A semiconductor device, comprising:
a memory cell, comprising:
a first electrode in a first dielectric layer; and
a second electrode in a second dielectric layer on the first dielectric layer; and
a data storage layer disposed in the second dielectric layer and surrounding the second electrode;
a first conductive line in the first dielectric layer;
a first conductive via on the first conductive line in the second dielectric layer, wherein surfaces of the second electrode and the data storage layer are substantially coplanar with a surface of the first conductive via.

10. The semiconductor device of claim 9, wherein a surface of the second dielectric layer is substantially coplanar with the surfaces of the second electrode, the data storage layer and the first conductive via.

11. The semiconductor device of claim 9, further comprising a first conductive pattern in a third dielectric layer being in direct contact with the second electrode, and a second conductive pattern in the third dielectric layer being in direct contact with the first conductive via.

12. The semiconductor device of claim 11, wherein the first conductive pattern is further in direct contact with the data storage layer.

13. The semiconductor device of claim 11, wherein first surfaces of the first conductive pattern, the second conductive pattern and the third dielectric layer are substantially coplanar, and second surfaces opposite to the first surfaces of the first conductive pattern, the second conductive pattern and the third dielectric layer are substantially coplanar.

14. The semiconductor device of claim 9, wherein the data storage layer is in direct contact with a sidewall and a surface of the second electrode, and the surface of the second electrode faces the first electrode.

15. A method of forming a semiconductor device, comprising:
forming a first electrode and a first conductive pattern;
forming a first dielectric layer on the first electrode and the first conductive pattern;
forming a first via hole and a second via hole in the first dielectric layer, to expose the first electrode and the first conductive pattern respectively;
forming an insulating layer in the first via hole;
forming a second electrode on the insulating layer to fill the first via hole; and
forming a first conductive via in the second via hole.

16. The method of claim 15, wherein forming the first via hole and the second via hole comprises:
forming a first etch stop layer on the first electrode and the first conductive pattern;
forming the first dielectric layer on the first etch stop layer; and
forming the first via hole and the second via hole in the first dielectric layer and the first etch stop layer.

17. The method of claim 15, wherein forming the insulating layer, the second electrode and the first conductive via comprises:
forming an insulating material on exposed surfaces of the first via hole and a top surface of the first dielectric layer while the second via hole is masking;
forming a conductive material on the insulating material to fill up the first via hole and the second via hole; and
removing the insulating material and the conductive material outside the first via hole and the second via hole, to form the insulating layer and the second electrode in the first via hole and the first conductive via in the second via hole.

18. The method of claim 15, further comprising:
forming a second etch stop layer on the first dielectric layer;
forming a second dielectric layer on the second etch stop layer;
forming a first opening and a second opening in the second etch stop layer and the second dielectric layer; and
forming a second conductive pattern in the first opening to electrically connect to the second electrode, and a third conductive pattern in the second opening to electrically connect to the first conductive via.

19. The method of claim 18, wherein forming the second conductive pattern and the third conductive pattern comprises:
forming a conductive material on the first dielectric layer to fill up the first opening and the second opening; and
removing the conductive material outside the first opening and the second opening, to form the second conductive pattern and the third conductive pattern.

20. The method of claim 19, wherein removing the conductive material outside the first opening and the second opening is performed by a planarization process.
